(19) United States
(12) Patent Application Publication
(10) Pub. No.: US 2009/0155459 A1
(43) Pub. Date: Jun. 18, 2009

(54) Method of forming active layer of organic solar cell using spray coating method

(76) Inventors: Doojin Park, Buk-gu (KR); Dong-Yu Kim, Buk-gu (KR); Jo Jang, Buk-gu (KR); Seok-Soon Kim, Buk-gu (KR)

Correspondence Address: HARNESS, DICKEY & PIERCE, P.L.C., P.O. BOX 8910, RESTON, VA, 20195, US

(21) Appl. No.: 12/222,926

(22) Filed: Aug. 20, 2008

(30) Foreign Application Priority Data
Dec. 17, 2007 (KR) 10-2007-0132221

(51) Int. Cl. B05D 5/12

(52) U.S. Cl. 427/74

(57) ABSTRACT

A method of forming an active layer of an organic solar cell using spray coating is provided. The method includes dissolving at least one material in a solvent to form a solution, preparing a coating material by diluting the solution, and spraying the coating material on a subject for spray coating. The spray coating does not need a vacuum chuck, and thus can be applied to a large-sized substrate, and a roll-to-roll method.

### CROSS-REFERENCE TO RELATED APPLICATION

This application claims the benefit of Korean Patent Application No. 2007-0132221, filed Dec. 17, 2007, the disclosure of which is hereby incorporated herein by reference in its entirety.

### BACKGROUND OF THE INVENTION

1. Field of the Invention

The present invention relates to a method of fabricating an organic solar cell using spray coating, and more particularly, to a method of forming an active layer of a solar cell using spray coating.

2. Description of the Related Art

Organic solar cells are generally formed of a polymer substrate, an organic electrode layer, a transport layer, an active layer and a metal electrode layer.

The polymer substrate is formed of glass or flexible polymer, and the organic electrode layer is formed of doped tin oxide or conductive polymer. Further, the transport layer is formed of an organic material such as PEDOT-PSS to facilitate hole transport, and the active layer is formed of organic semiconductor used as an electron donor, and organic semiconductor used as an electron acceptor. Finally, the metal electrode is formed of aluminum, silver, magnesium or calcium.

Such an organic solar cell in a multilayer structure is fabricated by spin coating or dip coating.

However, for spin coating, a vacuum chuck is essentially used to fix a substrate, so that this method cannot be applied to form an organic solar cell having a large-sized substrate or a flexible substrate.

On the other hand, for dip coating, a substrate is lifted at a constant speed from a solution to form a film, and thus has to be moved as slowly as possible to evaporate a solvent and obtain a uniform film. Thus, this method takes a long time to fabricate a solar cell, and is difficult to be applied for a large-sized substrate or a roll-to-roll process.

### SUMMARY OF THE INVENTION

The present invention provides a method of fabricating an organic solar cell using spray coating.

According to an embodiment of the present invention, a method of forming an active layer of an organic solar cell using spray coating, which can adjust absorption by spraying time, includes: dissolving at least one material in a solvent to form a solution; preparing a coating material by diluting the solution; and spraying the coating material on a subject for spray coating.

Here, the at least one material may include an electron donor material or electron acceptor material.

The active layer may include an electron donor layer in which electron donor materials are present in a higher concentration than electron acceptor materials, and an electron acceptor layer in which electron acceptor materials are present in a higher concentration than electron donor materials.

The electron donor material may include [6,6]-phenyl-C61-butyric acid methyl ester, and the electron acceptor material may include poly-3-hexylthiophene.

Here, the solvent may include chloroform, chlorobenzene, benzene, or dichlorobenzene.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic view showing a structure of an organic solar cell according to Example embodiment 1;

FIG. 2 is a view illustrating a method of forming an active layer according to Example embodiment 1;

FIG. 3A is a graph showing absorbance of active layers with different spraying time;

FIG. 3B is a graph of absorbance versus spraying time in a wavelength of 510 nm;

FIG. 4 is a graph of current density versus voltage for organic solar cells having active layers formed using various solvents;

FIG. 5A is a schematic view showing a structure of an organic solar cell according to Example embodiment 2;

FIG. 5B is a graph of current density versus voltage for the organic solar cells according to Example embodiments 1 and 2;

FIG. 6 is a graph showing the changes in parallel and series resistance characteristics of organic solar cells according to Example embodiments 1 and 2;

FIG. 7A is a schematic view showing a structure of a organic solar cell according to Example embodiment 3;

FIG. 7B is a graph of current density versus voltage according to Experimental example 4 and Example embodiment 3;

FIG. 8A is a graph of IPCE spectra for solar cells according to Example embodiment 1 and Comparative fabrication example 1; and

FIG. 8B is a graph of current density versus voltage for Example embodiment 1 and Comparative fabrication example 1.

### DETAILED DESCRIPTION OF THE INVENTION

Reference will now be made in detail to the present embodiments of the present invention, examples of which are shown in the accompanying drawings. It will be understood that the embodiments are described below in order not to limit the present inventions but to include modifications, equivalents and alternatives within the spirit and scope of the present invention.

“First” and “second” elements may be used to explain various elements, but the present invention is not limited to the number of the elements. These terms are used to distinguish one element from another element.

Hereinafter, the present invention will be described in detail with reference to the accompanying drawings. In the drawings, like reference numerals denote like elements.

### EXAMPLE EMBODIMENT 1

### Formation of Active Layer of Organic Solar Cell Using Spray Coating

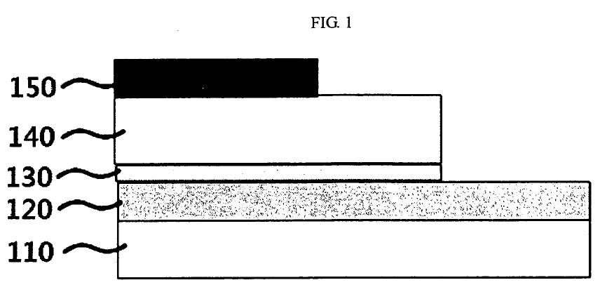

FIG. 1 is a schematic view showing a structure of an organic solar cell according to Example embodiment 1.

Referring to FIG. 1, first, a cleaned glass substrate 110 is prepared. An organic electrode layer 120 is formed on the glass substrate 110 using doped tin oxide. The glass substrate is used to measure UV absorption.

A transport layer 130 is formed on the organic electrode layer 120. The transport layer 130 is formed of a mixture of poly 3,4-ethylene dioxythiophene (PEDOT) and polystyrenesulfonate (PSS) by spin coating. The spin coating is performed at a speed of 5000 rpm, and then air-dried at 150° C. for 5 minutes.

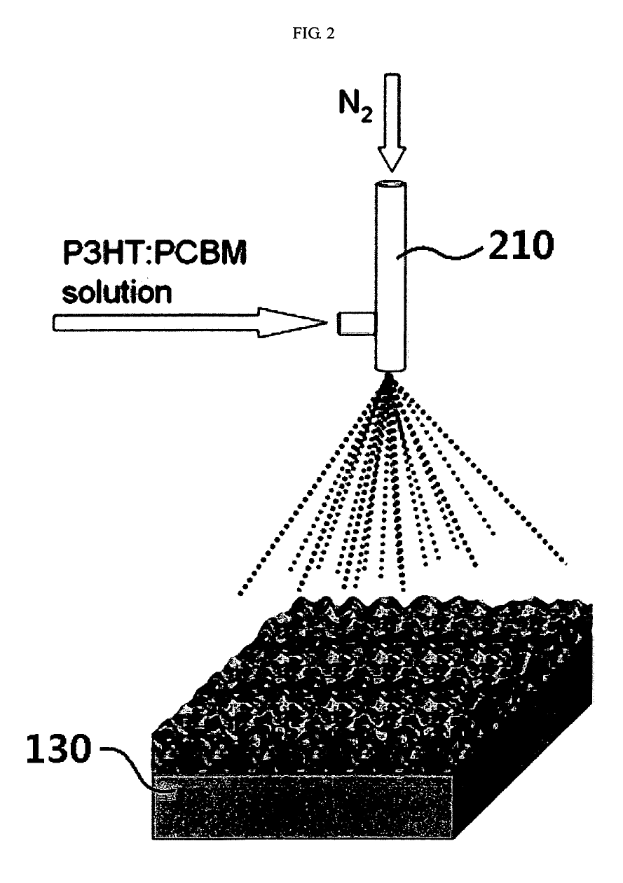

FIG. 2 is a view illustrating a method of forming an active layer according to Example embodiment 1.

Referring to FIGS. 1 and 2, an active layer 140 is formed on the transport layer 130 using spray coating method. The method of forming the active layer 140 includes forming a solution by dissolving a mixture of 15 mg poly-3-hexylthiophene (P3HT) and 7.5 mg [6,6]-phenyl-C61-butyric acid methyl ester (PCBM) in 1 mg chlorobenzene, forming a coating material by diluting the solution 10 times, and putting the coating material in an air brush 210 and applying the coating material onto the transport layer 130 using nitrogen at a pressure of 0.1 MPa.

After the spray coating process, the active layer 140 is dried using nitrogen at 110° C. for 7 minutes. The active layer 140 has an area of 0.164 cm².

A metal electrode layer 150 is formed by depositing 30 nm potassium and 150 nm aluminum on the active layer.

### EXPERIMENTAL EXAMPLE 1

### Correlation Test Between Spraying Time and Absorbance

Organic solar cells were fabricated by the same method as described in Example embodiment 1, except that active layers of the organic solar cells were formed at spraying time conditions of 5 s, 15 s, 30 s and 45 s, respectively.

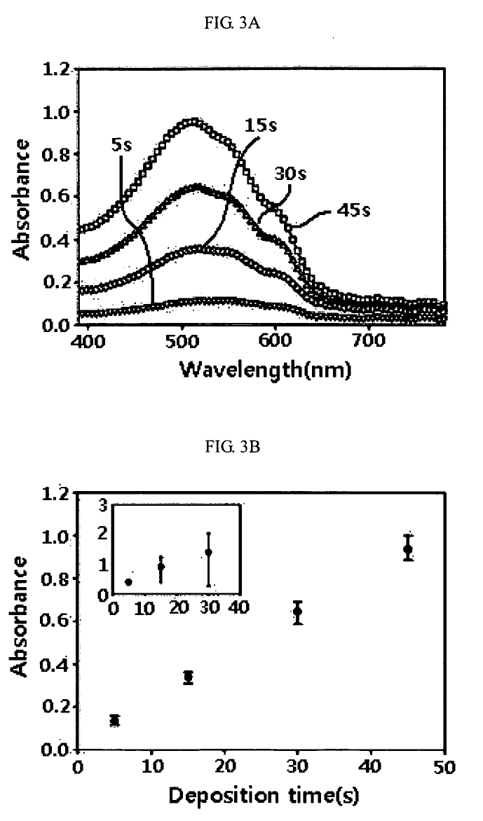

FIG. 3A is a graph showing absorbance of active layers with different spraying time in various wavelength regions adjusted using an AM 1.5 G filter.

Referring to FIG. 3A, the active layers have different absorbance at respective wavelengths according to spraying time. Thus, it can be noted that the characteristics of the active layer may be changed according to the spraying time. Further, in every test conducted in various spraying times, the highest absorption was shown in a wavelength of 510 nm.

FIG. 3B is a graph of absorbance versus spraying time in a wavelength of 510 nm.

Referring to FIG. 3B, it can be noted that the absorbance is in linear proportion to the spraying time in a wavelength of 510 nm. From the result, it can also be noted that the absorbance may be adjusted by spraying time.

### EXPERIMENTAL EXAMPLE 2

### Efficiency Test by Solvent

Organic solar cells were fabricated by the same method as described in Example embodiment 1, except that active layers of the organic solar cells were formed using chloroform(CF), chlorobenzene(CB), benzene and dichlorobenzene e.g., ODCB as solvents, respectively. Currents and voltages were measured in the organic solar cells having active layers formed using various solvents.

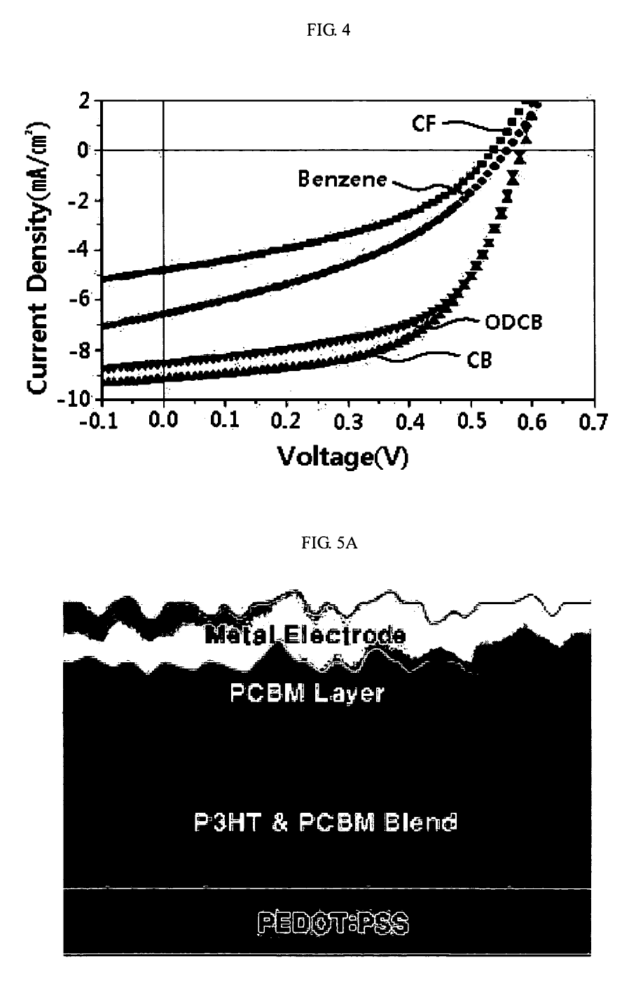

FIG. 4 is a graph of current density versus voltage for organic solar cells having active layers formed using various solvents according to Experimental example 2.

Referring to FIG. 4, the organic solar cell having an active layer formed using chlorobenzene(CB) as a solvent exhibits the highest energy efficiency. The energy efficiency is a ratio between actual maximum obtainable power density and input power density (100 mW/cm²), wherein the actual maximum obtainable power density is calculated by multiplying a current density and a voltage at the maximum power point.

### EXAMPLE EMBODIMENT 2

### Formation of Active Layer in a Multilayer Structure (1)

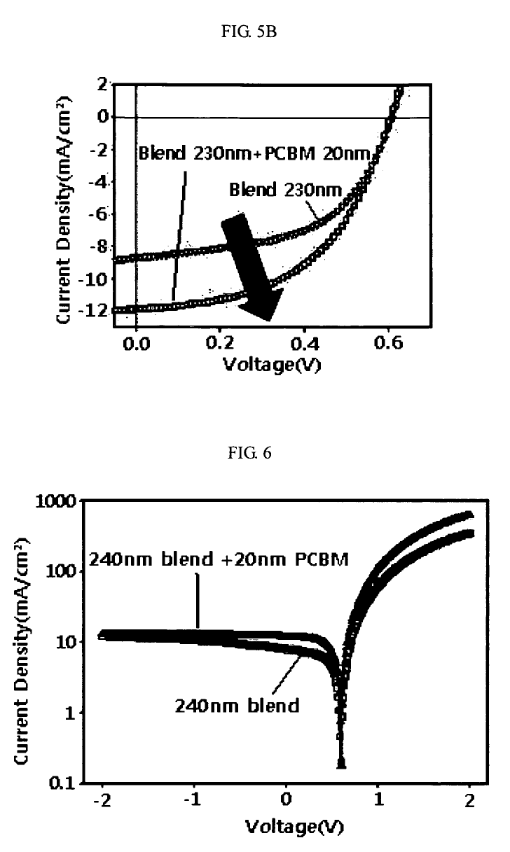

FIG. 5A is a schematic view showing a structure of an organic solar cell according to Example embodiment 2.

Referring to FIG. 5A, an organic solar cell is fabricated by the same method as described in Example embodiment 1, except that a first active layer(240 nm) is formed using a blend of P3HT and PCBM (P3HT:PCBM=1:0.5) and a second active layer (20 nm) is formed on the first active layer using PCBM (100%). The first and second active layers are formed using spray coating method as described in Example embodiment 1.

### EXPERIMENTAL EXAMPLE 3

### Characteristic Test for Organic Solar Cell Having Multilayer Active Layer (1)

Efficiency of the organic solar cell (thickness of active layer: 260 nm) fabricated according to Example embodiment 2 was compared to that of the organic solar cell according to Example embodiment 1.

FIG. 5B is a graph of current density versus voltage for the organic solar cells according to Example embodiments 1 and 2.

Referring to FIG. 5B, it can be noted that energy efficiency was improved in the organic solar cell further having a PCBM active layer as described in Example embodiment 2.

FIG. 6 is a graph showing the changes in parallel and series resistance characteristics of organic solar cells according to Example embodiments 1 and 2.

Referring to FIG. 6, the organic solar cell having a multilayer active layer according to Example embodiment 2 exhibited an improved rectification characteristic, an increased parallel resistance and a decreased series resistance, compared to the organic solar cell having a single active layer according to Example embodiment 1.

### EXAMPLE EMBODIMENT 3

### Formation of Active Layer Having Multilayer Structure (2)

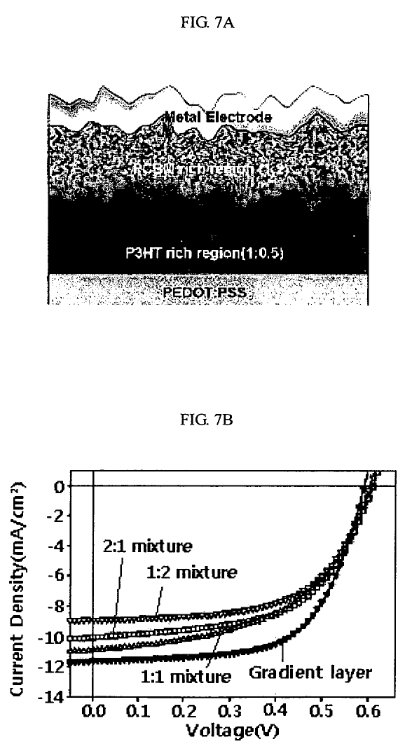

FIG. 7A is a schematic view showing a structure of a organic solar cell according to Example embodiment 3.

Referring to FIG. 7A, an organic solar cell is fabricated by the same method as described in Example embodiment 1, except that a first active layer having a thickness of 40 nm is formed of P3HT and PCBM at a ratio of 1:0.5, and thereon a second active layer having a thickness of 80 nm is formed of P3HT and PCBM at a ratio of 1:2. The first and second active layers are formed using spray coating method as described in Example embodiment 1.

### EXPERIMENTAL EXAMPLE 4

### Characteristic Test for Organic Solar Cell Having Multilayer Active Layer (2)

Organic solar cells were fabricated by the same method as described in Example embodiment 1, except that active layers of the organic solar cells were formed using P3HT and PCBM at various ratios of 2:1, 1:1 and 1:2, respectively.

FIG. 7B is a graph of current density versus voltage according to Experimental example 4 and Example embodiment 3.

Referring to FIG. 7B, it can be noted that the organic solar cell having two different active layers i.e., a gradient layer according to Example embodiment 3 exhibited better efficiency than other organic solar cells having single active layers independently formed of P3HT and PCBM at ratios of 2:1, 1:1 and 1:2. When the concentration ratios of P3HT to PCBM were 2:1, 1:1 and 1:2, efficiencies were independently 3.5, 3.4 and 3.2%. However, in Example embodiment 3, efficiency was 4.3%.

### COMPARATIVE FABRICATION EXAMPLE 1

### Formation of Active Layer by Spin Coating

An organic solar cell was fabricated by the same method as described in Example embodiment 1, except that an active layer was formed of P3HT and PCBM, which were dissolved in chlorobenzene, using spin coating.

### COMPARATIVE EXPERIMENTAL EXAMPLE 1

### Characteristic Test of Organic Solar Cell Having Active Layer Formed by Spin Coating

From the organic solar cells according to Example embodiment 1 and Comparative fabrication example 1, incident photon to current conversion efficiency (IPCE) spectra, voltages and currents were measured.

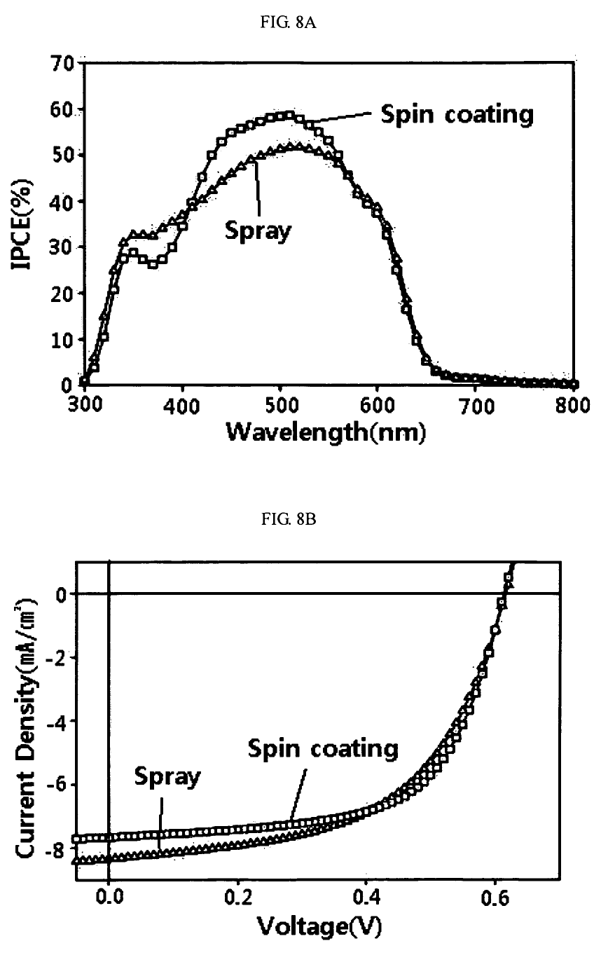

FIG. 8A is a graph of IPCE spectra for solar cells according to Example embodiment 1 and Comparative fabrication example 1.

Referring to FIG. 8A, the IPCE graph shows a wider absorption spectrum in Example embodiment 1 using spray coating than in Comparative fabrication example 1 using spin coating, even though active layers were formed of the same materials. This is because the active layer formed by spray coating has a rough surface, on which diff-used reflection occurs when light is reflected on a metal electrode, and thus energy is enabled to be converted with high efficiency even in a low absorption wavelength region.

FIG. 8B is a graph of current density versus voltage for Example embodiment 1 and Comparative fabrication example 1.

Referring to FIG. 8B, efficiencies in Comparative fabrication example 1 using spin coating and Example embodiment 1 using spray coating were about 2.8% and 2.9%, respectively, which indicated that there was no significant difference between the spray coating and the spin coating, even though the latter made a rougher surface.

As described above, an active layer can be formed by spray coating without additional equipment in a simple process. Further, the active layer formed by spray coating can be applied to a large-sized substrate or a flexible substrate.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A method of forming an active layer of an organic solar cell using spray coating, which can adjust absorption by spraying time, comprising:
dissolving at least one material in a solvent to form a solution;
preparing a coating material by diluting the solution; and
spraying the coating material on a subject for spray coating.

2. The method according to claim 1, wherein the at least one material includes an electron donor material or electron acceptor material.

3. The method according to claim 1, wherein the active layer includes:
an electron donor layer in which electron donor materials are present in a higher concentration than electron acceptor materials; and
an electron acceptor layer in which electron acceptor materials are present in a higher concentration than electron donor materials.

4. The method according to claim 2, wherein the electron donor material includes [6,6]-phenyl-C61-butyric acid methyl ester, and the electron acceptor material includes poly-3-hexylthiophene.

5. The method according to claim 1, wherein the solvent includes chloroform, chlorobenzene, benzene, or dichlorobenzene.
